(19) United States
(12) Patent Application Publication
(10) Pub. No.: US 2019/0181076 A1
(43) Pub. Date: Jun. 13, 2019

(54) METHOD OF MANUFACTURING LEADFRAMES OF SEMICONDUCTOR DEVICES,CORRESPONDING LEADFRAME AND SEMICONDUCTOR DEVICE

(71) Applicant: STMICROELECTRONICS S.R.L., Agrate Brianza (IT)

(72) Inventors: Dario VITELLO, Calolziocorte (IT); Fabio MARCHISI, Milano (IT); Alberto ARRIGONI, Eupilio (IT); Federico FREGO, Milano (IT); Federico Giovanni ZIGLIOLI, Pozzo d'Adda (IT); Paolo CREMA, Vimercate (IT)

(21) Appl. No.: 16/213,540

(22) Filed: Dec. 7, 2018

(30) Foreign Application Priority Data
Dec. 7, 2017 (IT) 102017000141565

(51) Int. Cl. H01L 23/495; H01L 21/48; B26F 1/38; B23C 3/13; C23F 1/02

(52) U.S. Cl. CPC H01L 23/49534; H01L 23/49582; H01L 21/4828; C23F 1/02; B26F 1/38; B23C 3/13; H01L 21/4842

(57) ABSTRACT

A method of producing leadframes for semiconductor devices comprises: providing a plurality of electrically-conductive plates, forming in the electrically conductive plates homologous passageway patterns according to a desired semiconductor device leadframe pattern, joining together the plurality of plates with the homologous passageway patterns formed therein mutually in register by producing a multilayered leadframe exhibiting the desired leadframe pattern and a thickness which is the sum of the thicknesses of the plates in the plurality of electrically-conductive plates.

### BACKGROUND

### Technical Field

The description relates to packaging of semiconductor devices such as, e.g., integrated circuits (IC's).

One or more embodiments may apply to producing leadframes of semiconductor devices.

### Description of the Related Art

Packaging of semiconductor devices such as integrated circuits involves the use of so-called leadframes, namely metal structures that permit exchange of signals towards and from a semiconductor chip or die in the package.

### BRIEF SUMMARY

Despite the quite extensive activity in that area, improved solutions for leadframe (LF) manufacturing are desirable. This may apply, e.g., to the possibility of increasing the number of leadcount (that is the number of input/output lines or leads) in a package without increasing the final size thereof.

One or more embodiments may relate to a corresponding leadframe and/or a corresponding semiconductor device.

The claims are an integral part of the technical teaching provided herein in respect of the embodiments.

One or more embodiments may provide a solution for leadframe manufacturing capable of increasing the number of leadcount in a semiconductor product package without increasing the final size thereof.

### BRIEF DESCRIPTION OF THE SEVERAL VIEWS OF THE DRAWINGS

One or more embodiments will now be described, by way of example only, with reference to the annexed figures, wherein:

FIGS. 1 and 2 are exemplary of methods of manufacturing leadframes,

FIG. 3 is a partially cutaway plan view of a leadframe,

FIG. 4 shows a portion of FIG. 3 as indicated by arrow IV, reproduced in a magnified scale,

FIG. 5 comprises three portions designated a), b), and c) illustrative of possible acts in embodiments, and

FIGS. 6 and 7 are illustrative of certain principles underlying one or more embodiments.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

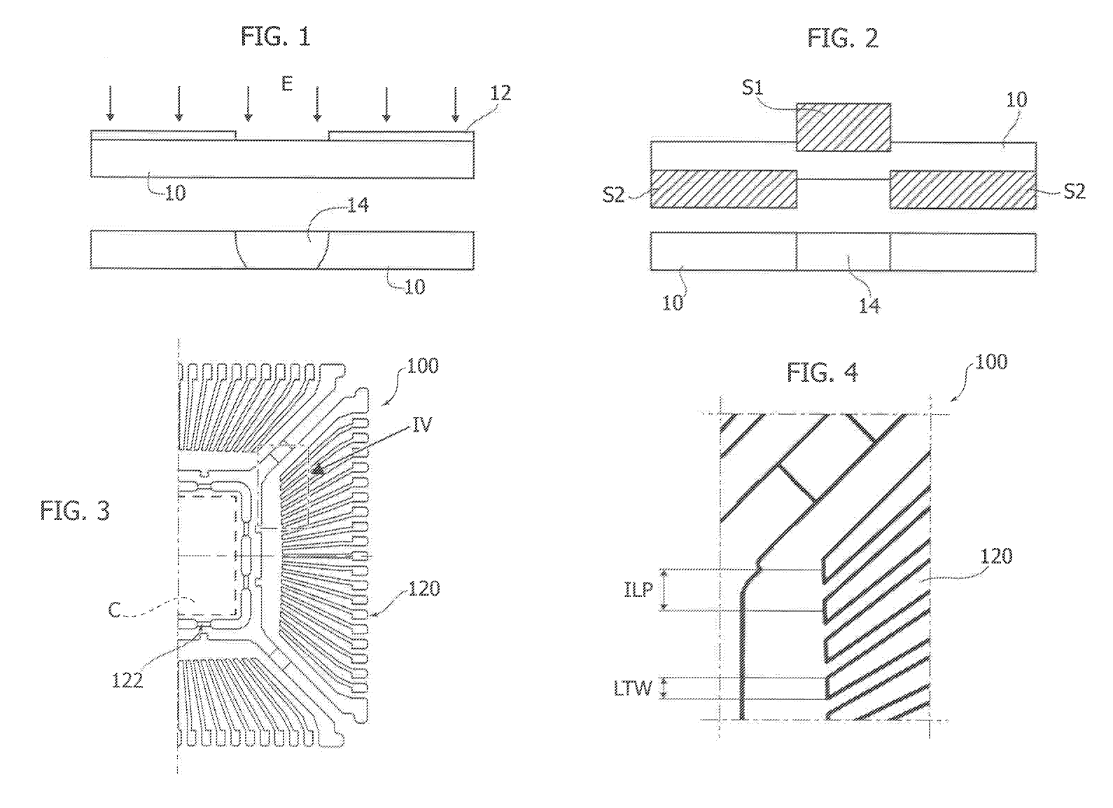

FIGS. 1 and 2 are illustrative of two conventional methods of manufacturing leadframes.

A leadframe is a metal structure provided in the package of a semiconductor device (an integrated circuit or IC, for instance) that permits exchange of signals towards and from a semiconductor chip or die in the package.

In a conventional manner, a leadframe can be produced starting from a (thin) flat plate of metal 10 (e.g., copper) to which etching processes (FIG. 1) or stamping processes (FIG. 2) may be applied.

In an exemplary etching process, the portion of the plate 10 not intended to be etched is covered with a protective material (e.g., a photoresist material) 12. An etching medium (e.g., a chemical) applied to the plate 10 will etch away those portions of the plate 10 not protected by the layer 12 to form therein a network of passageways (e.g., through slots across the plate thickness) 14 defining a leadframe pattern as desired.

In an exemplary stamping process as exemplified in FIG. 2, the plate 12 is subjected to stamping between complementary stamping tools S1, S2 so again a network of passageways 14 defining a leadframe pattern as desired is formed in the plate 10.

The details of processes as outlined in the foregoing are well known to those of skill in the art, thus making it unnecessary to provide a further detailed description herein.

It will be otherwise appreciated that various other methods of leadframe (LF) manufacturing by selectively removing material from a plate (e.g., plasma etching, laser beam etching, and so on) are known in the art which may be suited for LF manufacturing by taking advantage of the embodiments herein.

In fact one or more embodiments may be applied to manufacturing leadframes irrespective of the specific manufacturing process (e.g., various types of etching, stamping, and so on) adopted.

FIGS. 3 and 4 are exemplary of a leadframe 100 with a leadframe pattern comprising a (dense) array of leads 120 distributed around a central portion 122 intended to act as a support pad (die pad) for semiconductor chip or die C, whose outline is indicated in dashed line.

Selective electrical connection between the semiconductor die or chip C and the leads 120 may be provided, e.g., by means of a wire bonding layout (not visible in the figures) or other known means (e.g., ribbons).

As exemplified in FIG. 4 characteristics and performance (e.g., in terms of leadcount) of the leads 120 may be related to:
the lead pitch ILP, namely an (average) spacing between adjacent leads as measured between median points of the (inner) lead tips, and
the lead tip width LTW, namely an (average) width of the (inner) lead tips spacing between adjacent leads

Referring for both parameters to the “inner” lead tips is intended to take into account the possibility for the leads 120 to exhibit (as visible in FIGS. 3 and 4) a diverging or flared shape, with the leads becoming increasingly wider away from the center of the leadframe.

Referring for both parameters to the “average” is intended to take into account the possible presence of leads 120 of different widths, e.g., with wider leads used to carry power signals.

Increased leadframe robustness (e.g., for assembly, mounting, and operating life) is facilitated by increased thickness. Increased leadframe thickness may be obtained by increasing the thickness of the plate 10 as exemplified in FIGS. 1 and 2.

It is otherwise noted that parameters, such as inner lead pitch (ILP) or the lead tip width (LTW), may be related to the plate/leadframe thickness. For instance, ILP may increase with the leadframe thickness, e.g., with the spacing between adjacent leads about equal to the leadframe thickness (aspect ratio substantially equal to unity). This may be intrinsically related to the manufacturing processes (e.g., the tools used therein).

One or more embodiments aim at keeping constant the package size and leadframe thickness while also facilitating an increase in the number of leads 120 (namely the number of input/output lines towards and from a semiconductor chip in the package).

One or more embodiments may involve a “multilayer” manufacturing process wherein plural metal plates (e.g., two plates 101, 102) are subjected to stamping/etching processes, e.g., as exemplified in FIGS. 1 and 2 to provide therein a layout of passageways corresponding to a desired leadframe pattern, e.g., a desired layout of the leads 120 as exemplified in FIGS. 3 and 4.

As exemplified in FIG. 6, the plates 101, 102 (two plates are considered here for simplicity) may have, e.g., a thickness B/2 equal to, e.g., 0.1 mm. (this figure is purely exemplary and non-limitative).

The plates 101, 102 can then be joined together with the respective passageway layouts—assumed to be corresponding, e.g., identical—mutually in register so that the passageways 14 in the plate 101 will be (exactly) aligned with the passageways 14 in the plate 102.

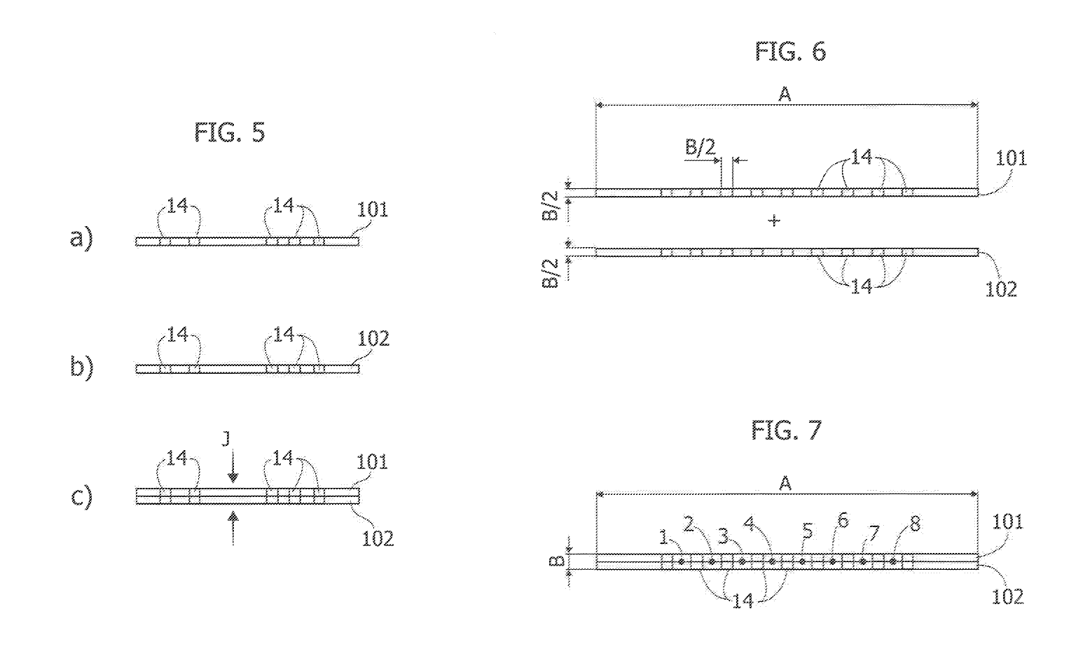

Joining the two plates 101, 102 as indicated at J in portion c) of FIG. 5 may involve the combined action of pressure and temperature.

Exemplary processes to join the plates 101, 102 may involve milling or extrusion under controlled atmosphere to avoid oxidation. Other conventional metal joining processes/methods as known in the art may be used in embodiments.

As exemplified in FIG. 7, joining together the two plates 101, 102 will produce a final “multilayer” leadframe wherein the width of the passageways 14 (which may dictate the pitch ILP and width LTW as exemplified in FIG. 4) will be retained while the overall thickness of the combined leadframe (101+102) will be equal to B/2+B/2=B.

In that way the limitations related to the aspect ratio of the passageways 14 may be overcome by facilitating the provision of thick leadframes (e.g., adapted to carry power signals) without an increased leadframe thickness penalizing leadframe performance in terms of lead pitch ILP and/or tip width LTW and, consequently, leadcount.

This result is exemplified in FIGS. 6 and 7. These figures show a portion A of leadframe wherein eight leads 1 to 8 (observed in cross-sectional view) are formed with the resulting leadframe of FIG. 7 having a thickness B twice the thickness B/2 of each individual plate 101, 102 in FIG. 6. FIGS. 6 and 7 show that lead parameters of the leads in the individual plates 101, 102 (e.g., ILP, LTW) are maintained unchanged in the final multilayer leadframe (101+102).

It will be otherwise appreciated that, in one or more embodiments, the solution exemplified in FIGS. 5, 6 and 7 may be extended to a multilayer leadframe produced by joining together three or more plates.

For instance, by joining three individual plates of thickness B/2, a resulting leadframe of thickness 3.B/2=1.5 B can be produced by again retaining in the resulting three-layer leadframe (of increased thickness 1.5 B) the lead parameters (e.g., ILP, LTW) of the leads in the individual plates which are joined together.

As noted, lead parameters such as ILP and LTW are a function of the leadframe thickness (e.g., with ILP/LTW smaller if the thickness decreases).

One or more embodiments thus facilitate obtaining, in a multi-layered leadframe, resulting values for parameters such as, e.g., ILP/LTW which are smaller if compared to those obtainable in a single-layer leadframe with the same thickness.

One or more embodiments thus facilitate increasing the overall number of leadcount without increasing the final package size.

It will be otherwise appreciated that one or more embodiments may involve joining together two or more plates that (other than the plates 101, 102 of equal thicknesses B/2 of FIGS. 5 to 7) may have different thicknesses.

A method according to one or more embodiments may comprise:
providing a plurality of electrically-conductive plates (e.g., 101, 102),
forming (e.g., E, S) in the electrically conductive plates in the plurality of electrically-conductive plates homologous passageway patterns (e.g., patterns of through slots 14 extending across the plate thickness) according to a certain semiconductor device leadframe pattern (see, e.g., 100 in FIGS. 3 and 4),
joining together (e.g., J) the plurality of plates with the homologous passageway patterns formed therein mutually in register (e.g., aligned with one another) by producing a multilayered leadframe exhibiting said leadframe pattern and a thickness (e.g., B) which is the sum of the thicknesses (e.g., B/2) of the plates in the plurality of electrically-conductive plates.

In one or more embodiments, the plurality of plates may comprise two electrically-conductive plates of equal thicknesses wherein the multilayered leadframe has a thickness twice said equal thicknesses.

In one or more embodiments, forming the passageway patterns in the electrically-conductive plates may comprise one of etching or stamping.

In one or more embodiments joining together the plurality of plates may comprise applying heat and pressure to the plurality of plates assembled together.

In one or more embodiments, joining together the plurality of plates may comprise one of milling or extrusion.

One or more embodiments may comprise joining together the plurality of plates under controlled atmosphere.

In one or more embodiments, a leadframe for semiconductor devices may comprise a plurality of electrically-conductive plates having homologous passageway patterns formed therein according to a certain semiconductor device leadframe pattern, the plurality of plates joined together with the homologous passageway patterns formed therein mutually in register to form a multilayered leadframe exhibiting said leadframe pattern and a thickness which is the sum of the thicknesses of the plates in the plurality of electrically-conductive plates.

In one or more embodiments, a semiconductor device may comprise:
a leadframe according to one or more embodiments having at least one die-mounting portion (see, e.g., 122 in FIG. 3), and
a semiconductor die or chip (see, e.g., C in FIG. 3) mounted at the at least one die-mounting portion in the leadframe.

The various embodiments described above can be combined to provide further embodiments. These and other changes can be made to the embodiments in light of the above-detailed description. Without prejudice to the underlying principles, the details and the embodiments may vary, even significantly, with respect to what has been described by way of example only, without departing from the extent of protection. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
in a plurality of plates of electrically conductive material, forming a network of passageways defining a leadframe pattern; and
coupling the plurality of plates together to form a multilayered leadframe, wherein the network of passageways of the plurality of plates are aligned with each other.

2. The method of claim 1, wherein the plurality of plates are two plates of equal thicknesses.

3. The method of claim 1, wherein forming the network of passageways comprises etching or stamping the plurality of plates.

4. The method of claim 1, wherein coupling the plurality of plates together comprises applying heat and pressure to the plurality of plates.

5. The method of claim 4, wherein coupling the plurality of plates comprises milling or extrusion.

6. The method of claim 1, wherein coupling the plurality of plates comprises coupling the plurality of plates in a controlled atmosphere.

7. The method of claim 1, wherein a thickness of the multilayered leadframe is greater than a distance between leads of the leadframe.

8. The method of claim 7, wherein the leads of the leadframe are defined by the network of passageways.

9. A leadframe, comprising:
a plurality of plates of electrically conductive material coupled together to form a multilayered leadframe, the plurality of plates having a network of passageways that are aligned with each other, wherein the network of passageways form a plurality of leads, a die pad, and tie bars, wherein a distance between adjacent leads of the plurality of leads is less than a thickness of the multilayered leadframe.

10. The leadframe of claim 9, wherein the distance between the adjacent leads is one half the thickness of the multilayered leadframe.

11. The leadframe of claim 9, wherein the plurality of plates are two plates, each plate having a same thickness as each other.

12. The leadframe of claim 9, wherein the plurality of plates are coupled together without adhesive material therebetween.

13. The leadframe of claim 9, wherein the leadframe includes a plurality of die pads, each die pad associated with a respective set of leads.

14. A semiconductor device, comprising:
a leadframe including a plurality of plates of electrically conductive material coupled together to form a multilayered leadframe, the plurality of plates having a network of passageways that are aligned with each other, wherein the network of passageways form a plurality of leads and a die pad, wherein a distance between adjacent leads of the plurality of leads is less than a thickness of the multilayered leadframe; and
a semiconductor chip coupled to the die pad.

15. The semiconductor device of claim 14, wherein the distance between the adjacent leads is one half the thickness of the multilayered leadframe.

16. The semiconductor device of claim 14, wherein the plurality of plates have a same thickness as each other.

17. The semiconductor device of claim 14, wherein the plurality of plates are first and second plates.

18. The semiconductor device of claim 17, wherein the first and second plates are coupled together without adhesive.

19. The semiconductor device of claim 14, wherein the plurality of plates are made of copper or a copper alloy.
